(19) United States
(12) Patent Application Publication
(10) Pub. No.: US 2026/0271595 A1
(43) Pub. Date: Sep. 10, 2026

(54) DISPLAY PANEL AND DISPLAY DEVICE

(71) Applicant: HKC CORPORATION LIMITED, Shenzhen (CN)

(72) Inventors: YAO LI, Shenzhen (CN); Pei XU, Shenzhen (CN)

(21) Appl. No.: 19/422,514

(22) Filed: Dec. 17, 2025

(30) Foreign Application Priority Data
Jan. 2, 2025 (CN) 202510004165.4

(51) Int. Cl. H10K 59/80; H10K 59/122

(52) U.S. Cl. CPC H10K 59/8791; H10K 59/122; H10K 59/873

(57) ABSTRACT

A display panel and a display device are disclosed. The display panel includes a substrate, a pixel-defining layer, a plurality of light-emitting elements, a compensation light source, an encapsulation layer and a light-shielding layer, the encapsulation layer overs the plurality of light-emitting elements, configured to seal the plurality of light-emitting elements; the light-shielding layer is disposed on the compensation light source, and located in the non-opening area, the light-shielding layer is configured to block outgoing light emitted perpendicular to the substrate from the compensation light source; the compensation light source is configured to provide compensation outgoing light in a preset angle to the plurality of light-emitting elements when two adjacent light-emitting elements of the plurality of light-emitting elements emit light for display, an intensity of the compensation outgoing light varies with that of light emitted from adjacent light-emitting elements.

### CROSS-REFERENCE TO RELATED APPLICATIONS

The present disclosure claims the priority and benefit of Chinese patent application number 2025100041654, titled “DISPLAY PANEL AND DISPLAY DEVICE” and filed on Jan. 2, 2025 with China National Intellectual Property Administration, the entire contents of which are incorporated herein by reference.

### TECHNICAL FIELD

The present disclosure relates to the technical field of display, and particularly to a display panel and a display device.

### BACKGROUND

The description provided in this section is intended for the mere purpose of providing background information related to the present disclosure but does not necessarily constitute prior art.

As a self-emissive display technology, Organic Light-Emitting Diode (hereinafter referred to as OLED) is increasingly applied in products. With growing public attention to privacy protection in modern society, adjustable viewing angle functionality (also known as anti-peeping) for display devices has become an essential feature. Therefore, OLED adjustable viewing angle technology has recently emerged as a key discussion topic.

Conventional anti-peeping displays attach anti-peeping films onto the display panel surface. Such films typically employ ultra-fine micro-louver technology, operating similarly to vertical blinds. A display scheme that restricts light from emitting at a fixed angle is relatively simple and straightforward, it has a relatively high yield and is relatively widely applied. However, anti-peeping films generally offer limited and non-adjustable viewing angles and protection levels. In conventional OLED products, viewing angle adjustment is primarily achieved by controlling the pixel opening area. Yet such adjustment methods remain fixed and often cause reduced luminance issues.

### SUMMARY

An objective of the present disclosure is to provide a display panel and a display device that implement wide or narrow viewing angle adjustment through a compensation light source, thereby improving wide-viewing-angle display performance without affecting normal display.

Disclosed in the present disclosure is a display panel, the display panel includes a substrate, a pixel-defining layer, a plurality of light-emitting elements, a compensation light source, an encapsulation layer and a light-shielding layer. The pixel-defining layer is disposed on the substrate, forming a plurality of opening areas. The plurality of light-emitting elements are disposed on the substrate, located in the plurality of opening areas respectively. The compensation light source is disposed on the pixel-defining layer, located in a non-opening area. The encapsulation layer is covering the plurality of light-emitting elements, configured to seal the plurality of light-emitting elements. The light-shielding layer is disposed on the compensation light source, and located in the non-opening area, configured to block outgoing light emitted perpendicular to the substrate from the compensation light source. The compensation light source is configured to provide compensation outgoing light in a preset angle to the plurality of light-emitting elements when two adjacent light-emitting elements of the plurality of light-emitting elements emit light for display, an intensity of the compensation outgoing light varies with that of light emitted from adjacent light-emitting elements.

The present disclosure further discloses a display device, the display device includes a drive circuit and a display panel, the drive circuit drives the display panel. The display panel includes a substrate, a pixel-defining layer, a plurality of light-emitting elements, a compensation light source, an encapsulation layer and a light-shielding layer. The pixel-defining layer is disposed on the substrate, forming a plurality of opening areas. The plurality of light-emitting elements are disposed on the substrate, located in the plurality of opening areas respectively. The compensation light source is disposed on the pixel-defining layer, located in a non-opening area. The encapsulation layer is covering the plurality of light-emitting elements, configured to seal the plurality of light-emitting elements. The light-shielding layer is disposed on the compensation light source, and located in the non-opening area, configured to block outgoing light emitted perpendicular to the substrate from the compensation light source. The compensation light source is configured to provide compensation outgoing light in a preset angle to the plurality of light-emitting elements when two adjacent light-emitting elements of the plurality of light-emitting elements emit light for display, an intensity of the compensation outgoing light varies with that of light emitted from adjacent light-emitting elements.

By setting the compensation light source, the compensation light source emits light from the non-opening area, and the light emitted in the direction perpendicular to the substrate is blocked by the light-shielding layer, so that the light emitted by the compensation light source obliquely exits from the plurality of opening area, thus forming compensation outgoing light with a certain angle. Moreover, the compensation outgoing light emitted by the compensation light source of the present disclosure may be adjusted according to the intensity emitted by the adjacent light-emitting elements. Therefore, clear display may be achieved under different display images, and the situation that the image is unable to be seen clearly at a large viewing angle due to the unadjustable intensity of the compensation outgoing light causing color mixing of the image does not occur. When the display panel needs wide angle display, the compensation light source is controlled to compensate for the light emission at a large viewing angle, and thus the adjustment of the wide and narrow viewing angles of the display panel is achieved by using the compensation light source. This enables people to clearly see the content displayed on the screen at a large viewing angle and improves the display quality.

### BRIEF DESCRIPTION OF DRAWINGS

The included drawings are provided for further understanding of embodiments of the present disclosure, constitute a part of the specification, illustrate embodiments of the present disclosure, and together with the text description, explain principles of the present disclosure. Obviously, the drawings in the following description are merely some embodiments of the present disclosure. For those of ordinary skill in the art, other drawings may be obtained based on these drawings without creative labor. In the drawings:

FIG. 1 is a schematic diagram of the display panel of a first embodiment of the present disclosure.

FIG. 2 is a schematic diagram of the display panel of a second embodiment of the present disclosure.

FIG. 3 is a schematic diagram of the display panel of a third embodiment of the present disclosure.

FIG. 4 is a driving schematic diagram of the non-visible light excitation layer of a fourth embodiment of the present disclosure.

FIG. 5 is a schematic diagram of the display panel of a fifth embodiment of the present disclosure.

FIG. 6 is a top-view schematic diagram of the display panel of the present disclosure.

FIG. 7 is a schematic diagram of the display device of the present disclosure.

### DETAILED DESCRIPTION OF EMBODIMENTS

It should be understood that the terminology, specific structures, and functional details disclosed herein are merely used to describe specific embodiments and are illustrative. However, the present disclosure may be implemented through many alternative forms and should not be construed as limited solely to the embodiments described herein.

In the description of the present disclosure, terms such as “first” and “second” are used solely for descriptive purposes and should not be interpreted as indicating relative importance or implicitly specifying the number of technical features indicated. Thus, unless otherwise specified, features qualified by “first” or “second” may explicitly or implicitly include one or more such features. “A plurality of” means two or more. Additionally, directional or positional terms such as “upper,” “lower,” “left,” “right,” “vertical,” or “horizontal” are described based on orientations or relative positional relationships shown in the accompanying drawings, which are used for simplified description to facilitate understanding of the present disclosure and do not imply that the devices or elements described should have specific orientations or be constructed or operated in specific orientations. These terms should not be construed as limiting the present disclosure. For those skilled in the art, the specific meaning of the above terms in the context of the present disclosure may be understood according to the specific situation.

The present disclosure is described below in detail with reference to the accompanying drawings and optional embodiments.

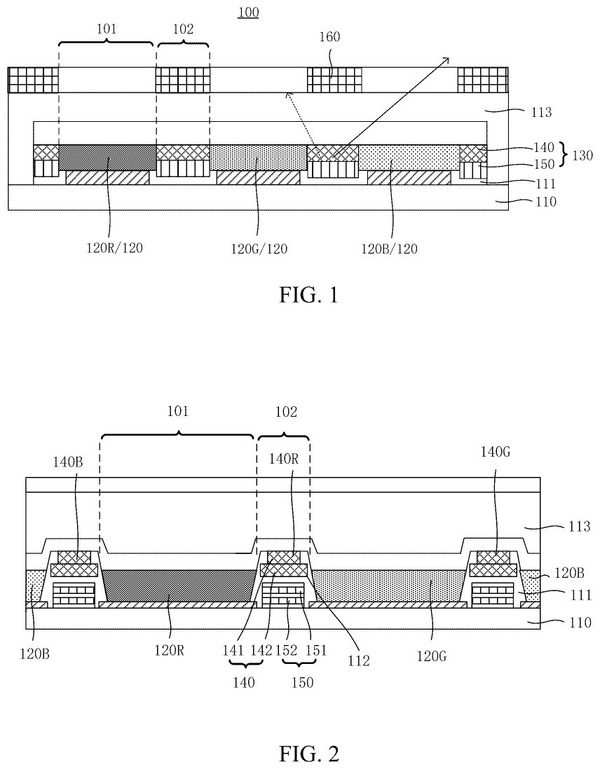

FIG. 1 is a schematic diagram of the display panel of the first embodiment of the present disclosure. Referring to FIG. 1, disclosed in the present disclosure is a display panel 100. The display panel 100 includes a substrate 110, a pixel-defining layer 111, a plurality of light-emitting elements 120, a compensation light source 130, an encapsulation layer 113, and a light-shielding layer 160. The pixel-defining layer 111 is disposed on the substrate 110, forming a plurality of opening areas 101. The plurality of light-emitting elements 120 are disposed on the substrate 110 and located in the plurality of opening areas 101 respectively. The compensation light source 130 is disposed on the pixel-defining layer 111 and located in a non-opening area 102. The encapsulation layer 113 is covering the plurality of light-emitting elements 120 and configured to seal the plurality of light-emitting elements 120. The light-shielding layer 160 is disposed on the compensation light source 130 and located in the non-opening area 102 for blocking outgoing light emitted perpendicular to the substrate 110 from the compensation light source 130. The compensation light source 130 is configured to provide compensation outgoing light in a preset angle to the plurality of light-emitting elements 120 when two adjacent light-emitting elements 120 of the plurality of light-emitting elements 120 emit light for display, an intensity of the compensation outgoing light varies with that of light emitted from adjacent light-emitting elements 120.

By setting the compensation light source 130, the compensation light source 130 emits light from the non-opening area 102, and the light emitted in the direction perpendicular to the substrate 110 is blocked by the light-shielding layer 160, so that the light emitted by the compensation light source 130 obliquely exits from the plurality of opening area 101, thus forming compensation outgoing light with a certain angle. Moreover, the compensation outgoing light emitted by the compensation light source 130 of the present disclosure may be adjusted according to the intensity emitted by the adjacent light-emitting elements 120. Therefore, clear display may be achieved under different display images, and the situation that the image is unable to be seen clearly at a large viewing angle due to the unadjustable intensity of the compensation outgoing light causing color mixing of the image does not occur. The compensation light source 130 is controlled to compensate for the light emission at a large viewing angle when the display panel 100 needs wide angle display, and thus the adjustment of the wide and narrow viewing angles of the display panel 100 is achieved by using the compensation light source 130. This enables people to clearly see the content displayed on the screen at a large viewing angle and improves the display quality.

It is worth mentioning that the display pixels seen by the user at the side viewing angle are inaccurate due to the insufficient brightness of the light emitted by the pixels of the display panel 100 at the side viewing angle, when the angle between the viewing direction of the human eye and the display screen of the display panel 100 is less than or equal to 60 degrees. Therefore, it is necessary to compensate for the light emitted at the side viewing angle. Moreover, under different display grayscales, that is, compensation outgoing light with different brightnesses is required to compensate for the side view display when the light intensities emitted by different color light-emitting elements 120 of the display panel 100 are different. Therefore, the preset angle in the compensation outgoing light provided in the present embodiment, mainly the compensation outgoing light at a large viewing angle, may generally be in a range from 12 degrees to 60 degrees to compensate for the side view display within the abovementioned range.

Specifically, the compensation light source 130 in the present embodiment mainly utilizes the property that metal-organic framework material may emit visible light under the excitation of non-visible light to achieve the expansion of the display viewing angle. The advantage of the metal-organic framework material of the present disclosure is that there is no need to provide voltage for driving inside the display panel 100. Instead, the metal-organic framework material needs to be excited by non-visible light to emit light. That is, the compensation light source 130 may be disposed in the non-opening area 102, for example, on the pixel-defining layer 111 or other positions, which is easy to implement and may be set by occupying a relatively small space. Compared with the solution in the exemplary technology where the compensation light source 130 is synchronously disposed in the non-opening area 102 by using the light-emitting element 120, there is no need to occupy too much area and does not need to modify the non-opening position within the pixel. The position of the opening needs to be squeezed due to the problem of the area occupied by the device of the light-emitting element 120, when the light-emitting element 120 is employed in the non-opening area 102. When three sub-pixels originally constitute one pixel, at this time, within one pixel, the compensation sub-pixel also occupies an area, so that four sub-pixels need to be set, resulting in a reduction in the opening area and causing display problems.

Specifically, the compensation light source 130 includes a non-visible light excitation layer 150 and a light compensation layer 140. The light compensation layer 140 is formed of a metal-organic framework material, and the metal-organic framework material includes lanthanide metal-organic framework material. The light compensation layer 140 is configured to generate visible light under non-visible light excitation, and the visible light includes any one of blue light, green light or red light. The non-visible light excitation layer 150 is configured to emit non-visible light under voltage driving.

Specifically, the metal-organic framework material is a porous material formed by the self-assembly of metal ions and organic ligands. Both metal ions and organic ligands may serve as potential luminescent centers, and the pores of metal-organic framework materials (hereinafter referred to as MOFs) may also accommodate luminescent guests. The metal-organic framework material in the present embodiment may emit monochromatic or polychromatic light. Under the excitation of non-visible light, the colors of the light emitted by adding different organic ligands or metal ions are also different. For example, lanthanide metal-organic framework material ions (such as Ln³⁺, Eu³⁺, Tb³⁺and Dy³⁺) and organic ligands with non-uniformly distributed carboxyl groups (such as isophthalic acid derivatives) first assemble into a belt-like structure through the anisotropic growth of metal ions and organic ligands, and then these nanobands entwine and undergo gelation to form a MOF gel. By adjusting the types and/or ratios of Ln³⁺ions, a mixed-metal MOF gel with full color emission may be prepared. The coordination center lanthanide metal-organic framework material ions (Eu³⁺, Tb³⁺or Dy³⁺) may produce emissions of different colors, thus achieving the controllability of multiple colors under excitation of the identical wavelength. At the same time, emissions of the identical color at different wavelengths may be achieved by changing the types and ratios of ions.

The metal-organic framework material in the present embodiment is mainly lanthanide metal-organic framework material. Lanthanide metal-organic framework material has the characteristic of emitting light under the excitation of non-visible light and has multiple forms of luminescence, such as simultaneous luminescence of ligands and metal ions, simultaneous luminescence of host and guest, simultaneous luminescence of mixed metals, and simultaneous luminescence of mixed MOFs. Taking the simultaneous luminescence of ligands and metal ions as an example, the lanthanide metal-organic framework material ions in the lanthanide metal-organic framework material have the antenna effect, that is, the ligand absorbs energy to the excited state, undergoes intersystem crossing to the triplet state, and the triplet state sensitizes the lanthanide ions to achieve antenna effect luminescence. To achieve the simultaneous luminescence of ligands and metal ions, the energy transfer efficiency from the ligand to the europium ions may be regulated by introducing a boronic acid group onto terephthalic acid. By using the simultaneous luminescence of ligands and metal ions, the boronic acid group has a strong affinity for fluoride ions and H₂O₂, realizing the ratio-type luminescence sensing and visual detection of fluoride ions and H₂O₂. Different from regulating energy transfer, the intramolecular rotation of the ligand is restricted by coordination to enhance luminescence when preparing MOFs from aggregation induced emission ligands and lanthanide ions, combined with the antenna effect luminescence of europium ions, so as to achieve the simultaneous enhanced luminescence of the ligand and europium ions. For example, by adjusting the ratio of lanthanide ions and ligands, taking Ln-MOF[TbₓEu₁₋ₓ(TCBA)(H₂O)]₂·DMF as an example, where Eu(III) is characterized by emitting red light, Tb(III) is characterized by emitting green light, and Gd(III) is characterized by emitting blue light, the color of luminescence may be changed by adjusting the ratio of Eu(III), Tb(III), and Gd(III). That is, MOFs with different luminescent colors may be achieved by combining different ligands and metal ions. Whereas for simultaneous host-guest luminescence, mixed metal luminescence, and mixed MOFs luminescence, the employed ligands and metal ions typically differ. Taking simultaneous host-guest luminescence as an example with Ru@MIL-NH₂ material: Ru(bpy)₃²⁺ exhibits red fluorescence, and MIL-NH₂ exhibits blue fluorescence. Under single wavelength excitation at 300 nm, the MOF achieves blue-red host-guest luminescence. For the simultaneous luminescence of mixed metals, since Ln³⁺ ions have similar atomic radii and coordination modes, mixed lanthanide metal-organic framework material MOFs may be easily prepared by adjusting the ratio of Ln³⁺ ions. Making use of the red, green, and blue luminescence of Eu³⁺, Tb³⁺, and Dy³⁺. For the simultaneous luminescence of mixed MOFs, using Eu³⁺ and Tb³⁺ as metal nodes, reacting with 2,5-benzenedicarboxylic acid boronic acid to prepare red-light Eu-MOFs and green-light Tb-MOFs respectively, together with blue-light UiO-66-NH₂, tricolor MOFs inks may be prepared.

In addition to the four luminescence paradigms for achieving multi-luminescent lanthanide metal-organic framework material mentioned above, mixed ligands as luminescent centers and single ligands with multi-luminescence may also be configured to prepare multi-luminescent MOFs. Among them, by adjusting the ratios of Eu(III), Tb(III), and Gd(III), or the ratios of Eu³⁺, Tb³⁺, and Dy³⁺, and selecting the wavelength of invisible light between 250 nm and 350 nm, lanthanide metal-organic framework material of different materials may exhibit different luminescent colors. In the present embodiment, it is mainly utilized that lanthanide metal-organic framework material may emit monochromatic light such as red, green or blue under different material ratios, achieving red light compensation, green light compensation and blue light compensation.

FIG. 2 is a schematic diagram of the display panel of the second embodiment of the present disclosure. As shown in FIG. 2, in the present embodiment, the light compensation layer 140 includes at least a first light compensation section 141 and a second light compensation section 142. The non-visible light excitation layer 150 includes at least a first excitation layer 151 and a second excitation layer 152. The first light compensation section 141 is configured to emit first compensation outgoing light under control of the first excitation layer 151, and the second light compensation section 142 is configured to emit second compensation outgoing light under control of the second excitation layer 152. The first excitation layer 151 and the second excitation layer 152 have different ranges in non-visible light wavelength.

In the present embodiment, two light compensation sections are taken as an example for illustration. In practice, the amount of light compensation sections is not limited to two and needs to be designed according to the actual situation. In this solution, it is mainly considered that under high grayscale display and low-grayscale display, especially when adjacent pixels are in high-grayscale and low-grayscale respectively, if the compensation light of the two pixels is the equal, display problems such as low contrast occur. Therefore, in the present embodiment, it is necessary to distinguish the light compensation for the side-view angles of high-grayscale and low-grayscale. For example, the brightness of the compensation light is greater under high-grayscale, and the compensation brightness is less under low-grayscale, so as to achieve a better compensation effect.

Specifically, in the present embodiment, the first excitation layer 151 and the second excitation layer 152 emit light with different wavelengths, so that the first light compensation section 141 and the second light compensation section 142 may be controlled to work separately or simultaneously, achieving at least two-step light compensation brightness for the first light compensation section 141, the second light compensation section 142, or the first light compensation section 141 and the second light compensation section 142 are simultaneous operation. Of course, by continuously increasing the amount of light compensation sections, compensation with more step-by-step brightness levels may be achieved.

In one or more embodiments, the brightness of the first light compensation section 141 and that of the second light compensation section 142 may be the same or different. When the brightness of the first light compensation section 141 is identical to that of the second light compensation section 142, it is necessary to control the first light compensation section 141 and the second light compensation section 142 to turn on simultaneously and separately to achieve different compensation brightness levels. In the case of setting the brightness of the first light compensation section 141 and that of the second light compensation section 142 to be different, multi-step brightness compensation may be achieved by separately controlling the first light compensation section 141 or the second light compensation section 142 to turn on or off.

Specifically, taking the case where the brightness of the first light compensation section 141 and the second light compensation section 142 are set to be different as an example, the intensity of the first compensation outgoing light is less than that of the second compensation outgoing light. The first light compensation section 141 operates when an intensity of light emitted from the plurality of light-emitting elements 120 is within a first range, the second light compensation section 142 operates when the intensity of light emitted from the plurality of light-emitting elements 120 is within a second range. For example, the display pixels with grayscales from 0 grayscale to 127 grayscales may be configured such that the first compensation outgoing light is in operation when the display panel 100 displays with 256 grayscales, and the display pixels with grayscales from 128 to 255 may be configured such that the second compensation outgoing light is in operation, achieving compensation for low grayscale display by the first light compensation section 141 and compensation for high-grayscale display by the second light compensation section 142.

Generally, the first light compensation section 141 and the second light compensation section 142 need to be controlled according to the grayscale displayed by the adjacent light-emitting elements 120. Of course, the first light compensation section 141 and the second light compensation section 142 may also be controlled by regions, or according to the overall value of the displayed grayscale. For example, the second light compensation section 142 is controlled to operate when more than half of the pixels in the current display screen are in high-grayscale display. The first light compensation section 141 is controlled to operate when more than half of the pixels in the current display panel 100 are in low-grayscale display. It is highly feasible and has a significant effect on improving the side-view image although the above-mentioned overall value control method is not sufficiently precise and accurate.

Continuing to refer to FIG. 2, in the present embodiment, the first light compensation section 141 and the second light compensation section 142 are respectively disposed on the pixel-defining layer 111. The first light compensation section 141 and the second light compensation section 142 are respectively disposed in the grooves 112 when there are grooves 112 on the pixel-defining layer 111. Of course, when there are no grooves 112 on the pixel-defining layer 111, the first light compensation section 141 and the second light compensation section 142 are disposed between the pixel-defining layer 111 and the encapsulation layer 113.

In the present solution, by setting grooves 112 on the pixel-defining layer 111, the first light compensation section 141 and the second light compensation section 142 are hidden in the grooves 112, and the pixel-defining layer 111 separates the light compensation parts from the plurality of light-emitting elements 120, avoiding the light compensation parts from interfering with the plurality of light-emitting elements 120. The light compensation parts may be formed in the grooves 112 by coating or printing since the light compensation parts are formed of lanthanide metal-organic framework material, reducing the impact on other film layers.

In the present embodiment, the first light compensation section 141 is disposed on the second light compensation section 142, and the first excitation layer 151 is disposed on the second excitation layer 152. Non-visible light emitted by the second excitation layer 152 passes through the first excitation layer 151 and enters the second light compensation section 142.

In actual design, due to the small area of the non-opening area 102 and the small width of the pixel-defining layer 111 between adjacent light-emitting elements 120, the designed areas for the first light compensation section 141 and the second light compensation section 142 are insufficient. Therefore, by means of a stacked layer setting, the first light compensation section 141 and the second light compensation section 142 may be simultaneously disposed in the groove 112 of the pixel-defining layer 111, and the control of the first light compensation section 141 and the second light compensation section 142 may be achieved by adjusting non-visible light of different wavelengths.

Specifically, an area of the first light compensation section 141 is less than that of the second light compensation section 142. By setting the areas of the first light compensation section 141 and the second light compensation section 142 to be different, the second light compensation section 142 and the first light compensation section 141 have different compensation light intensities, thus achieving compensation for different lights.

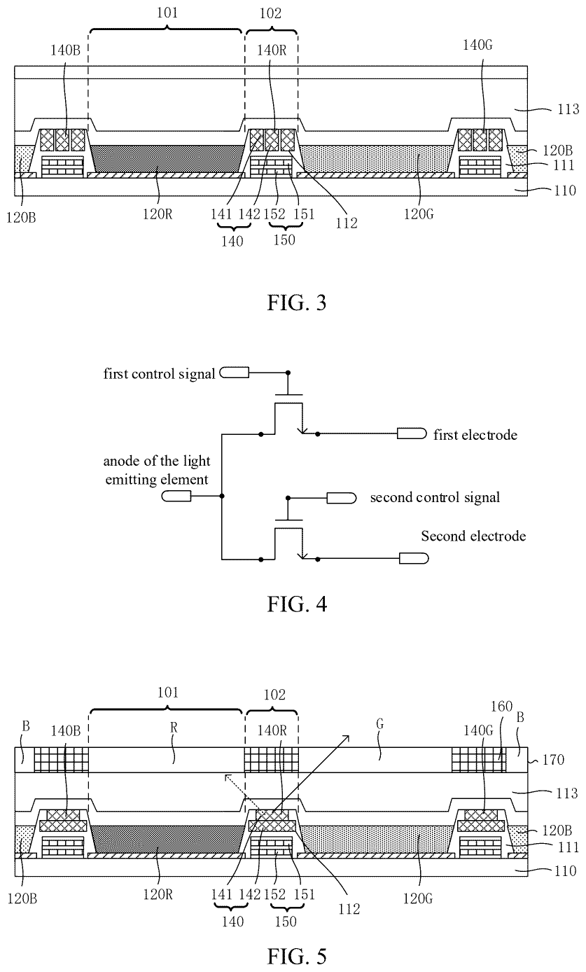

FIG. 3 is a schematic diagram of the display panel of the third embodiment of the present disclosure. As shown in FIG. 3, in one or more embodiments, the second light compensation section 142 is disposed surrounding the first light compensation section 141, and the first light compensation section 141 is coplanar with the second light compensation section 142. By reducing the areas of the first light compensation section 141 and the second light compensation section 142 on the pixel-defining layer 111, the first light compensation section 141 is coplanar with the second light compensation section 142, thus achieving different brightness compensations by adjusting the first light compensation section 141 and the second light compensation section 142 respectively. In the present embodiment, due to the different position settings of the second light compensation section 142 and the first light compensation section 141, the large viewing angle viewing angles of the two also differ. The second light compensation section 142 arranged on the outer side, because it is disposed near the opening area 101, has a less deviation in the emission angle compared to the first light compensation section 141, that is, the side view angle compensation angle of the first light compensation section 141 is larger. As a result, users may see the compensation outgoing light from the first light compensation section 141 at a larger side viewing angle, achieving light compensation at a larger angle.

Furthermore, from the cross-section of two adjacent light-emitting elements 120, the width of the pixel-defining layer 111 is equal to the distance between two adjacent light-emitting elements 120. The width of the groove 112 needs to be less than that of the pixel-defining layer 111, and a part of the pixel-defining layer 111 is required to separate the light compensation layer 140 from the plurality of light-emitting elements 120. When the first light compensation section 141 and the second light compensation section 142 are arranged on the identical layer, the width of the first light compensation section 141 accounts for approximately one-half to one-third (including the end-point values) of the width of the groove 112, so that the width of the middle area accounts for approximately one-half to one-third of the width of the groove 112. Of course, it is necessary to design more gradients if there are more light compensation layers 140. For example, the central area is the first light compensation section 141, and surrounding the central area extending outwards in sequence may include the second light compensation section 142, . . . , the n^{th} light compensation part, achieving a multi-gradient surround. The n^{th} light compensation part is the n^{th} viewing angle gradient, and the area design of each gradient is not fixed and is set according to the angle. Correspondingly, there are also n non-visible light excitation layers 150 below, such as the first excitation layer 151, the second excitation layer 152, . . . , the n^{th} excitation layer. The first excitation layer 151, the second excitation layer 152, . . . , the n^{th} excitation layer are arranged in a stacked manner, and the non-visible light excitation layer 150 set on the upper layer is driven through a transparent conductive layer. It is worth mentioning that the on-off of the light compensation layer 140 in the present embodiment may achieve the control of the variable viewing angle, and by setting multiple sets of light compensation parts, the step-by-step adjustment of different viewing angles may be achieved, thus realizing the adjustment of the variable viewing angle in a limited space. For the display panel 100 in the present embodiment, the area of the opening area 101 may be appropriately reduced, thereby increasing the area of the non-opening area 102. When the compensation light source 130 is not working, it is a narrow-viewing-angle display with a certain anti-peeping ability. When the compensation light source 130 is working, it is a wide-viewing-angle display, thus achieving a wider display effect. Of course, the adjustment of the wide and narrow viewing angles, as in the above mentioned embodiments, is also applicable when the first light compensation layer 140 and the second light compensation layer 140 are arranged in a stacked manner.

Furthermore, the light compensation layer 140 includes a plurality of sets of light compensation sections, the non-visible light excitation layer 150 includes multiple groups of excitation layers that emit non-visible light of different wavelengths. An amount of the light compensation sections is identical to that of the excitation layers, and one set of light compensation sections is configured to emit compensation outgoing light under control of one set of excitation layers.

In the present embodiment, the luminous intensity of each group of light compensation sections may be controlled to be the same or different. In the case where the luminous intensity of each group of light compensation sections are the same, the compensation brightness may be controlled by adjusting the number of light compensation sections. In the case where the luminous intensity of each group of light compensation sections are different, different compensation brightness levels may be achieved by separately controlling the light compensation sections with different brightnesses. It may be understood that, if multiple sets of light compensation sections are arranged on the identical layer, it also means that a larger area of the non-opening area 102 is required to accommodate this part. In this solution, considering the area of the pixel-defining layer 111, a stacked arrangement of multiple sets of light compensation sections may be adopted to achieve multi-step brightness compensation.

Specifically, the display panel 100 controls the amount of operating excitation layers to control the intensity of the compensation outgoing light from the light compensation sections. The greater the luminous intensity of the plurality of light-emitting elements 120 is, the larger the plurality of operating excitation layers is. In the present embodiment, the intensity of the compensation outgoing light with stepped changes is set according to the plurality of light compensation sections to adapt to different grayscale changes. For example, when set to four steps, the grayscale is correspondingly divided into four stages to match them, thus forming better light compensation.

FIG. 4 is a driving schematic diagram of the non-visible light excitation layer of the present disclosure. As shown in FIG. 4, for the driving of the first excitation layer 151 and the second excitation layer 152, they need to be displayed or turned off simultaneously with the corresponding light-emitting element 120. The first excitation layer 151 and the second excitation layer 152 respectively require two electrodes for driving. However, considering that the first excitation layer 151 and the second excitation layer 152 are arranged in a stacked manner, the first excitation layer 151 and the second excitation layer 152 may share one electrode. Thus, they may be driven by controlling the other electrode of the first excitation layer 151 and the second excitation layer 152. The first excitation layer 151 serves as the first electrode, and the second excitation layer 152 serves as the second electrode. The first excitation layer 151 is driven by a first active switch, and the second excitation layer 152 is driven by a second active switch. The gate of the first active switch is connected to a first control signal, the input end of the first active switch is connected to the anode (bottom electrode) of the corresponding light-emitting element 120, and the output end of the first active switch is connected to the first electrode. The gate of the second active switch is connected to a second control signal, the input end of the second active switch is connected to the anode of the above mentioned light-emitting element 120, and the output end of the second active switch is connected to the second electrode. Under the control of the first control signal and the second control signal, when the above-mentioned light-emitting element 120 emits light, the first excitation layer 151 or the second excitation layer 152 may be controlled to operate. The first control signal and the second control signal are mainly determined according to the grayscale of the display screen.

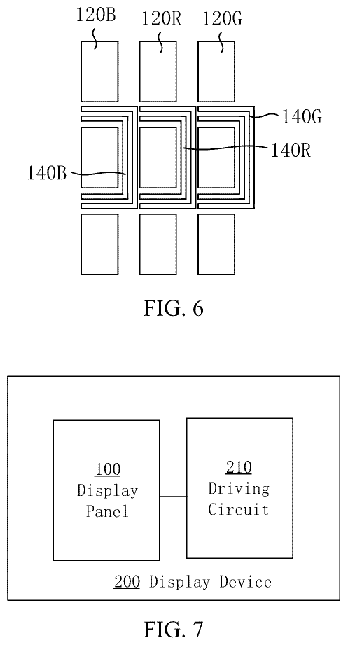

FIG. 5 is a schematic diagram of the display panel of the fourth embodiment of the present disclosure, and FIG. 6 is a top view schematic diagram of the display panel of the present disclosure. As shown in FIGS. 5 to 6, specifically, the display panel 100 includes red sub-pixels R, green sub-pixels G and blue sub-pixels B. The plurality of light-emitting elements 120 includes red light-emitting elements 120R, green light-emitting elements 120G and blue light-emitting elements 120B. Red light-emitting elements 120R are disposed corresponding to red sub-pixels R, green light-emitting elements 120G are disposed corresponding to green sub-pixels G, and blue light-emitting elements 120B are disposed corresponding to blue sub-pixels B.

When the light emitted by the light compensation layer 140 of the present disclosure is monochromatic light, the light compensation layer 140 corresponding to the luminous color needs to be disposed at the position of the sub-pixel of the corresponding color. Specifically, the light compensation layer 140 includes a red light compensation layer 140R, a green light compensation layer 140G and a blue light compensation layer 140B. The red light compensation layer 140R is disposed on one side or multiple sides of red light-emitting elements 120R, the green light compensation layer 140G is disposed on one side or multiple sides of green light-emitting elements 120G, and the blue light compensation layer 140B is disposed on one side or multiple sides of blue light-emitting elements 120B.

The red light compensation layer 140R mainly emits red light, the blue light compensation layer 140B mainly emits blue light, and the green light compensation layer 140G mainly emits green light. The red light compensation layer 140R, the green light compensation layer 140G and the blue light compensation layer 140B that emit light of different colors may be formed by using lanthanide metal-organic framework material formed with different ligands or metal ions.

In one or more embodiments, the display panel 100 of the present embodiment is a display panel 100 with a new technology of replacing a polarizer with COE (Color film on Encapsulation, forming a color filter on a thin-film encapsulation structure). That is, a color filter layer 170 is further provided on the encapsulation layer 113. The color filter layer 170 is provided with color filter parts corresponding to the opening area 101. Generally, the color filter parts include a red filter part, a green filter part, and a blue filter part. Three adjacent color filter parts of different colors may form a pixel, which are respectively called a red sub-pixel R, a green sub-pixel G and a blue sub pixel B. The quantities of light passing through the red filter part, the green filter part and the blue filter part change by controlling the luminous intensities of the light-emitting elements 120 at the positions corresponding to the red sub-pixel R, the green sub-pixel G and the blue sub-pixel B, achieving color display within a pixel. Any color may be formed within a pixel, that is, different color displays are achieved by controlling the grayscale of the red sub-pixel R, the grayscale of the green sub-pixel G, and the grayscale of the blue sub-pixel B. Moreover, in the present embodiment, the above-mentioned light shielding layer 160 may be formed on the identical layer as the color filter parts. The black matrix in the color filter layer 170 is configured as the light shielding layer 160.

In one or more embodiments, the display panel 100 of the present embodiment may also be a display panel 100 with a polarizer, that is, a polarizer (polarizing film) is provided on the upper part of the display panel 100. The polarizing film is mainly configured to reduce the reflection problem of ambient light, and there is no need to set up a color filter layer 170. When a monochromatic light compensation part is set between light emitting elements 120 of different colors and the emitted light of the monochromatic light compensation part exits from the opening area 101 corresponding to light emitting elements 120 of different colors, there will be a color-mixing problem because the function of the polarizing film is mainly polarization and it does not filter the wavelength of light. For example, if a red light compensation layer 140R is set between a red sub-pixel R and a green sub-pixel G, when the compensation outgoing light of the red light compensation layer 140R exits from the area of the red sub-pixel R, it compensates for the large viewing angle. However, when the compensation outgoing light of the red light compensation layer 140R exits from the blue sub-pixel B, it will cause color mixing in the side viewing angle of the blue sub-pixel B, thus forming an anti peeping effect. Therefore, in the display panel 100 with a polarizer, when the red light compensation layer 140R is set on the right side of the red sub-pixel R, it will form an effect of anti peeping from the left hand viewing angle and light compensation from the right hand viewing angle, that is, the left hand viewing angle may not be seen clearly while the right hand large viewing angle may be seen more clearly. The COE display panel 100 does not have the above mentioned phenomenon. Since a blue filter part is set on the blue sub-pixel B. the red light emitted by the red light compensation layer 140R may not pass through the blue filter part. Therefore, the COE display panel 100 forms a single side large viewing angle compensation effect.

Specifically, only one color of light compensation layer 140 is set between two adjacent light-emitting elements 120 of different colors. Thus, a single side large viewing angle compensation is achieved. Taking a display panel 100 with vertical monochromatic and horizontal RGB cyclic arrangement as an example, a red light compensation layer 140R may be disposed between two adjacent red sub-pixels R, a green light compensation layer 140G may be disposed between two adjacent green sub-pixels G, and a blue light compensation layer 140B may be disposed between two adjacent blue sub-pixels B. Only one color of light compensation layer 140 is disposed between two sub-pixels of different colors. For example, a red light compensation layer 140R is disposed between a red sub-pixel R and a green sub-pixel G, a green light compensation layer 140G is disposed between a green sub-pixel G and a blue sub-pixel B, and a blue light compensation layer 140B is disposed between a blue sub-pixel B and a red sub-pixel R. Generally, light compensation layers 140 of the identical color may be uniformly disposed on the left or right side of the sub-pixels of the corresponding color, thus achieving large viewing angle light compensation on the left or right side.

FIG. 7 is a schematic diagram of the display device of the present disclosure As shown in FIG. 7, the present disclosure also discloses a display device. The display device 200 includes a driving circuit 210 and a display panel 100, where the driving circuit 210 is configured to drive the display panel 100 to display.

It should be noted that the inventive concept of the present disclosure may be formed into many embodiments, but limitations of the disclosure document preclude exhaustive listing. Therefore, should no conflict be present, the various embodiments or technical features described above may be arbitrarily combined to form new embodiments. After the various embodiments or technical features are combined, the original technical effects may be enhanced.

The foregoing content describes the present disclosure in further detail i conjunction with specific optional embodiments, but it should not be construed that the specific implementation of the present disclosure is limited solely to these descriptions. For those of ordinary skill in the art to which the present disclosure pertains, several simple deductions or replacements may be made without departing from the inventive concept of the present disclosure, and these should all be regarded as falling within the protection scope of the present disclosure.

What is claimed is:

1. A display panel, comprising:
a substrate;
a pixel-defining layer, disposed on the substrate, forming a plurality of opening areas;
a plurality of light-emitting elements, disposed on the substrate, located in the plurality of opening areas respectively;
a compensation light source, disposed on the pixel-defining layer, located in a non-opening area;
an encapsulation layer, covering the plurality of light-emitting elements, configured to seal the plurality of light-emitting elements; and
a light-shielding layer, disposed on the compensation light source, and located in the non-opening area, configured to block outgoing light emitted perpendicular to the substrate from the compensation light source;
wherein the compensation light source is configured to provide compensation outgoing light in a preset angle to the plurality of light-emitting elements when two adjacent light-emitting elements of the plurality of light-emitting elements emit light for display, an intensity of the compensation outgoing light varies with that of light emitted from adjacent light-emitting elements.

2. The display panel according to claim 1, wherein the compensation light source comprises a non-visible light excitation layer and a light compensation layer;
the light compensation layer is formed of a metal-organic framework material, the metal-organic framework material comprises a lanthanide metal-organic framework material, the light compensation layer is configured to generate visible light under non-visible light excitation, and the visible light comprises any one of blue light, green light or red light; and
the non-visible light excitation layer is configured to emit non-visible light under voltage driving.

3. The display panel according to claim 2, wherein the light compensation layer comprises at least a first light compensation section and a second light compensation section;
the non-visible light excitation layer comprises at least a first excitation layer and a second excitation layer, the first light compensation section is configured to emit first compensation outgoing light under control of the first excitation layer, the second light compensation section is configured to emit second compensation outgoing light under control of the second excitation layer, the first excitation layer and the second excitation layer have different ranges in non-visible light wavelength.

4. The display panel according to claim 3, wherein an intensity of the first compensation outgoing light is less than that of the second compensation outgoing light;
the first light compensation section operates when an intensity of light emitted from the plurality of light-emitting elements is within a first range, the second light compensation section operates when the intensity of light emitted from the plurality of light-emitting elements is within a second range.

5. The display panel according to claim 3, wherein a plurality of grooves are provided on the pixel-defining layer, the first light compensation section and the second light compensation section are respectively disposed in the plurality of grooves.

6. The display panel according to claim 5, wherein the first light compensation section is disposed on the second light compensation section, an area of the first light compensation section is less than that of the second light compensation section;
the first excitation layer is disposed on the second excitation layer, non-visible light emitted by the second excitation layer passes through the first excitation layer and enters the second light compensation section.

7. The display panel according to claim 5, wherein the second light compensation section is disposed surrounding the first light compensation section, and the first light compensation section is coplanar with the second light compensation section.

8. The display panel according to claim 2, wherein the display panel comprises red sub-pixels, green sub-pixels and blue sub-pixels, the plurality of light-emitting elements comprise red light-emitting elements, green light-emitting elements and blue light-emitting elements, the red light-emitting elements are disposed corresponding to the red sub-pixels, the green light-emitting elements are disposed corresponding to the green sub-pixels, the blue light-emitting elements are disposed corresponding to the blue sub-pixels;
the light compensation layer comprises a red light compensation layer, a green light compensation layer and a blue light compensation layer, the red light compensation layer is disposed on one or more sides of the red light-emitting elements, the green light compensation layer is disposed on one or more sides of the green light-emitting elements, and the blue light compensation layer is disposed on one or more sides of the blue light-emitting elements; and
only one color of light compensation layer is disposed between two adjacent light-emitting elements of different colors.

9. The display panel according to claim 2, wherein the light compensation layer comprises a plurality of sets of light compensation sections, the non-visible light excitation layer comprises multiple groups of excitation layers that emit non-visible light of different wavelengths; an amount of the light compensation sections is identical to that of the excitation layers, and one set of light compensation sections is configured to emit compensation outgoing light under control of one set of excitation layers.

10. The display panel according to claim 9, wherein the display panel controls the amount of operating excitation layers to control the intensity of the compensation outgoing light from the light compensation sections; when the greater the luminous intensity of the plurality of light-emitting elements is, the larger the plurality of operating excitation layers is.

11. The display panel according to claim 10, wherein a range of the preset angle is from 12 degrees to 60 degrees.

12. The display panel according to claim 4, wherein the first compensation outgoing light operates when the intensity of light emitted from the plurality of light-emitting elements is within a first range, the second compensation outgoing light operates when the intensity of light emitted from the plurality of light-emitting elements is within a second range.

13. The display panel according to claim 12, wherein a range of the first range is from 0 grayscale to 127 grayscales, a range of the second range is from 125 grayscales to 255 grayscales.

14. A display device, comprising a drive circuit and a display panel, the drive circuit drives the display panel, the display panel comprises:
a substrate;
a pixel-defining layer, disposed on the substrate, forming a plurality of opening areas;
a plurality of light-emitting elements, disposed on the substrate, located in the plurality of opening areas respectively;
a compensation light source, disposed on the pixel-defining layer, located in a non-opening area;
an encapsulation layer, covering the plurality of light-emitting elements, configured to seal the plurality of light-emitting elements; and
a light-shielding layer, disposed on the compensation light source, and located in the non-opening area, configured to block outgoing light emitted perpendicular to the substrate from the compensation light source;
wherein the compensation light source is configured to provide compensation outgoing light in a preset angle to the plurality of light-emitting elements when two adjacent light-emitting elements of the plurality of light-emitting elements emit light for display, an intensity of the compensation outgoing light varies with that of light emitted from adjacent light-emitting elements.

15. The display device according to claim 14, wherein the compensation light source comprises a non-visible light excitation layer and a light compensation layer;
the light compensation layer is formed of a metal-organic framework material, the metal-organic framework material comprises a lanthanide metal-organic framework material, the light compensation layer is configured to generate visible light under non-visible light excitation, and the visible light comprises any one of blue light, green light or red light;
the non-visible light excitation layer is configured to emit non-visible light under voltage driving.

16. The display device according to claim 14, wherein the light compensation layer comprises at least a first light compensation section and a second light compensation section;
the non-visible light excitation layer comprises at least a first excitation layer and a second excitation layer, the first light compensation section is configured to emit first compensation outgoing light under control of the first excitation layer, the second light compensation section is configured to emit second compensation outgoing light under control of the second excitation layer, the first excitation layer and the second excitation layer have different ranges in non-visible light wavelength.

17. The display device according to claim 16, wherein an intensity of the first compensation outgoing light is less than that of the second compensation outgoing light;
the first light compensation section operates when an intensity of light emitted from the plurality of light-emitting elements is within a first range, the second light compensation section operates when the intensity of light emitted from the plurality of light-emitting elements is within a second range.

18. The display device according to claim 16, wherein a plurality of grooves are provided on the pixel-defining layer, the first light compensation section and the second light compensation section are respectively disposed in the plurality of grooves.

19. The display device according to claim 17, wherein the first light compensation section is disposed on the second light compensation section, an area of the first light compensation section is less than that of the second light compensation section;
the first excitation layer is disposed on the second excitation layer, non-visible light emitted by the second excitation layer passes through the first excitation layer and enters the second light compensation section.

20. The display device according to claim 17, wherein the second light compensation section is disposed surrounding the first light compensation section, and the first light compensation section is coplanar with the second light compensation section.
